(19) United States
(12) Patent Application Publication
(10) Pub. No.: US 2025/0151577 A1
(43) Pub. Date: May 8, 2025

(54) DISPLAY DEVICE

(71) Applicant: Wuhan China Star Optaciectronics Semiconductor Display Technology Co., Lid., Wuhan (CN)

(72) Inventor: Wenqiang WANG, Wuhan (CN)

(21) Appl. No.: 17/793,398

(22) PCT Filed: Jun. 29, 2022
(86) PCT No.: PCT/CN2022/102255

§ 371 Date: Jan. 15, 2025

(30) Foreign Application Priority Data
May 30, 2022 (CN) 202210601425.2

(51) Int. Cl. H10K 59/80; G06F 1/16; H05K 1/18; H10K 102/00

(52) U.S. Cl. CPC H10K 59/873; G06F 1/1616; G06F 1/1652; G06F 1/1656; G06F 1/1681; H05K 1/189; H05K 2201/10128; H10K 2102/311

(57) ABSTRACT

The present application provides a display device. The display device includes a display panel and an encapsulation protection assembly. The display panel includes a support layer and a panel body disposed on the support layer. The encapsulation protection assembly includes a protection layer and a frame. The frame is disposed on one side of the support layer away from the panel body, and the protection layer is disposed on one side of the panel body away from the support layer. Edges of the protection layer surround a periphery of the display panel, extend to one side of the support layer away from the panel body, and are connected to the frame.

### FIELD OF DISCLOSURE

The present application relates to a field of display technology and in particular, to a display device.

### DESCRIPTION OF RELATED ART

Organic light-emitting diode (OLED) display devices have been widely used due to their advantages such as ultra-high contrast ratio, wide color gamut, fast response, active light emission, flexibility, and bendability.

At present, the OLED display device is provided with lines such as gate signal lines, voltage signal lines, and driving signal lines at side edges. Usually, the side edges of the OLED display device are more likely to be damaged by external impact or scratching, especially in a bendable or foldable OLED display device. Therefore, a front frame structure is usually used to protect the OLED display device. However, when the front frame structure is assembled with the OLED display device, it occupies a certain space at edges of the display device. This reduces a screen ratio and also affects the overall visual experience provided by the display device.

### SUMMARY OF INVENTION

### Technical Problems

The present application provides a display device to solve a technical problem that a screen ratio is reduced because a conventional front frame structure occupies a certain space at edges of an organic light-emitting diode (OLED) display device after assembled to the display device.

### SOLUTION TO PROBLEM

### Technical Solutions

The present application provides a display device, comprising.

a display panel comprising a support layer and a panel body disposed on the support layer; and

an encapsulation protection assembly comprising a protection layer and a frame, wherein the frame is disposed on one side of the support layer away from the panel body, and the protection layer is disposed on one side of the panel body away from the support layer, wherein edges of the protection layer surround a periphery of the display panel, extend to one side of the support layer away from the panel body, and are connected to the frame.

In the display device of the present application, wherein the protection layer comprises a main protection portion disposed on one side of the panel body away from the support layer and comprises an edge protection portion disposed at a periphery of the main protection portion, the edge protection portion comprises a lateral side protection sub-portion disposed around the periphery of the display panel and an connection sub-portion extending from one side of the lateral side protection sub-portion away from the main protection portion to one side of the support layer facing away from the panel body, and the frame is connected to the connection sub-portion and disposed on one side of the support layer away from the panel body; and

wherein the encapsulation protection assembly is connected to the display panel at least through the main protection portion.

In the display device of the present application, the display panel comprises a bending display portion and two flat display potions disposed at two sides of the bending display portion;

the frame is spaced apart from the display panel, and the frame comprises a first opening at a position corresponding to the bending display portion; and

the edge protection portion is spaced apart from the display panel, and the edge protection portion comprises a second opening at a position corresponding to the bending display portion.

In the display device of the present application, the edge protection portion comprises two first protection sections disposed on opposite side edges of the display panel, two second protection sections disposed on opposite ends of the display panel, and a plurality of corner protection sections each disposed at a corner of the display panel;

each of the corner protection sections is disposed between one of the first protection sections and one of the second protection sections, each of the corner protection section is spaced apart from one of the first protection sections, and each of the corner protection sections is spaced apart from one of the second protection sections; and

the first protection section extends along a first direction, the bending display portion comprises a bending axis extending along a second direction, a predetermined angle is included between the second direction and the first direction, the second opening comprises two sub-openings corresponding to the bending display portion, and the two sub-openings are arranged in the two first protection sections respectively.

In the display device of the present application, the display panel comprises a bent state which bending about the bending axis;

when the display panel is in the bent state, at a side edge of one of the flat display portions away from the bending display portion, a displacement distance from an end surface of the support layer to a plane where an end surface of the main protection portion is located is less than or equal to a predetermined distance, and a distance between one of the first protection sections and an adjacent one of the corner protection sections is greater than the predetermined distance.

In the display device of the present application, the frame comprises two sub-frames, each of the sub-frames is disposed corresponding to one of the flat display portions, and the two sub-frames are spaced apart at the first openings;

in the two flat display portions, a flexible circuit board is disposed at one end of one of the flat display portions away from the bending display portion;

in the two second protection sections, one of the second protection sections close to the flexible circuit board is provided with a preset opening at a position corresponding to the flexible circuit board; and

in the two sub-frames, one of the sub-frames close to the flexible circuit board is provided with a clearance opening at a position corresponding to the flexible circuit board.

In the display device of the present application, each of the sub-frames is U-shaped and is disposed at an edge of the support layer on one side away from the panel body.

In the display device of the present application, the display device further comprises a middle frame, the middle frame comprises a bendable hinge disposed corresponding to the bending display portion and two frame bodies respectively connected with the bendable hinge, the bendable hinge includes two movable ends, and the two frame bodies are connected to the two movable ends of the bending hinge respectively; and

each of the frame bodies includes a connecting protrusion and an accommodating groove matched with one of the sub-frames, each of the connecting protrusions is connected to one side of the support layer away from the panel body, the connection sub-portion and the sub-frames are disposed in the accommodating grooves, the connection sub-portion is spaced apart from the middle frame, and the sub-frames are spaced apart from the middle frame.

In the display device of the present application, each of the frame bodies further comprises a side frame portion disposed at one side of the lateral side protection sub-portion away from the display panel; in each of the frame bodies, the accommodating groove is located between the connecting protrusion and the side frame portion; and the lateral side protection sub-section is spaced apart from the side frame portions.

In the display device of the present application, a first adhesive layer is disposed on one side of the connecting protrusion close to the support layer, and the connecting protrusion is connected to the support layer through the first adhesive layer.

In the display device of the present application, a second adhesive layer is disposed on one side of the main protection portion close to the panel body, and the main protection portion is connected to the panel body through the second adhesive layer.

In the display device of the present application, the frame is disposed between the connection sub-section and the support layer, one side of the frame is connected to the support layer, and another side of the frame is connected to the connection sub-portion.

The present application further provides a display device, comprising:

a display panel comprising a support layer and a panel body disposed on the support layer; and

an encapsulation protection assembly comprising a protection layer and a frame, wherein the frame is disposed on one side of the support layer away from the panel body, and the protection layer is disposed on one side of the panel body away from the support layer, wherein edges of the protection layer surround a periphery of the display panel, extend to one side of the support layer away from the panel body, and are connected to the frame;

wherein the protection layer comprises a main protection portion disposed on one side of the panel body away from the support layer and comprises an edge protection portion disposed at a periphery of the main protection portion, the edge protection portion comprises a lateral side protection sub-portion disposed around the periphery of the display panel and an connection sub-portion extending from one side of the lateral side protection sub-portion away from the main protection portion to one side of the support layer facing away from the panel body, and the frame is connected to the connection sub-portion and disposed on one side of the support layer away from the panel body;

the encapsulation protection assembly is connected to the display panel at least through the main protection portion;

the display panel comprises a bending display portion and two flat display potions disposed at two sides of the bending display portion;

the frame is spaced apart from the display panel, and the frame comprises a first opening at a position corresponding to the bending display portion;

the edge protection portion is spaced apart from the display panel, and the edge protection portion comprises a second opening at a position corresponding to the bending display portion; and

a second adhesive layer is disposed on one side of the main protection portion close to the panel body, and the main protection portion is connected to the panel body through the second adhesive layer.

In the display device of the present application, the edge protection portion comprises two first protection sections disposed on opposite side edges of the display panel, two second protection sections disposed on opposite ends of the display panel, and a plurality of corner protection sections each disposed at a corner of the display panel;

each of the corner protection sections is disposed between one of the first protection sections and one of the second protection sections, each of the corner protection section is spaced apart from one of the first protection sections, and each of the corner protection sections is spaced apart from one of the second protection sections; and

the first protection section extends along a first direction, the bending display portion comprises a bending axis extending along a second direction, a predetermined angle is included between the second direction and the first direction, the second opening comprises two sub-openings corresponding to the bending display portion, and the two sub-openings are arranged in the two first protection sections respectively.

In the display device of the present application, the display panel comprises a bent state which bending about the bending axis; and

when the display panel is in the bent state, at a side edge of one of the flat display portions away from the bending display portion, a displacement distance from an end surface of the support layer to a plane where an end surface of the main protection portion is located is less than or equal to a predetermined distance, and a distance between one of the first protection sections and an adjacent one of the corner protection sections is greater than the predetermined distance.

In the display device of the present application, the frame comprises two sub-frames, each of the sub-frames is disposed corresponding to one of the flat display portions, and the two sub-frames are spaced apart at the first openings;

in the two flat display portions, a flexible circuit board is disposed at one end of one of the flat display portions away from the bending display portion;

in the two second protection sections, one of the second protection sections close to the flexible circuit board is provided with a preset opening at a position corresponding to the flexible circuit board; and

in the two sub-frames, one of the sub-frames close to the flexible circuit board is provided with a clearance opening at a position corresponding to the flexible circuit board.

In the display device of the present application, each of the sub-frames is U-shaped and is disposed at an edge of the support layer on one side away from the panel body.

In the display device of the present application, the display device further comprises a middle frame, the middle frame comprises a bendable hinge disposed corresponding to the bending display portion and two frame bodies respectively connected with the bendable hinge, the bendable hinge includes two movable ends, and the two frame bodies are connected to the two movable ends of the bending hinge respectively; and

each of the frame bodies includes a connecting protrusion and an accommodating groove matched with one of the sub-frames, each of the connecting protrusions is connected to one side of the support layer away from the panel body, the connection sub-portion and the sub-frames are disposed in the accommodating grooves, the connection sub-portion is spaced apart from the middle frame, and the sub-frames are spaced apart from the middle frame.

In the display device of the present application, each of the frame bodies further comprises a side frame portion disposed at one side of the lateral side protection sub-portion away from the display panel; in each of the frame bodies, the accommodating groove is located between the connecting protrusion and the side frame portion; and the lateral side protection sub-section is spaced apart from the side frame portions.

In the display device of the present application, a first adhesive layer is disposed on one side of the connecting protrusion close to the support layer, and the connecting protrusion is connected to the support layer through the first adhesive layer.

### ADVANTAGES OF INVENTION

### Beneficial Effects

The protection layer is arranged on one side of a panel body away from the support layer. The edges of the protection layer surround the periphery of the display panel, extend to one side of the support layer away from the panel body, and are connected to the frame. Accordingly, the present application realizes encapsulation and protection for surfaces and the periphery of the panel body without reducing a screen ratio of the display device.

### BRIEF DESCRIPTION OF DRAWINGS

### Description of Attached Drawings

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without inventive work.

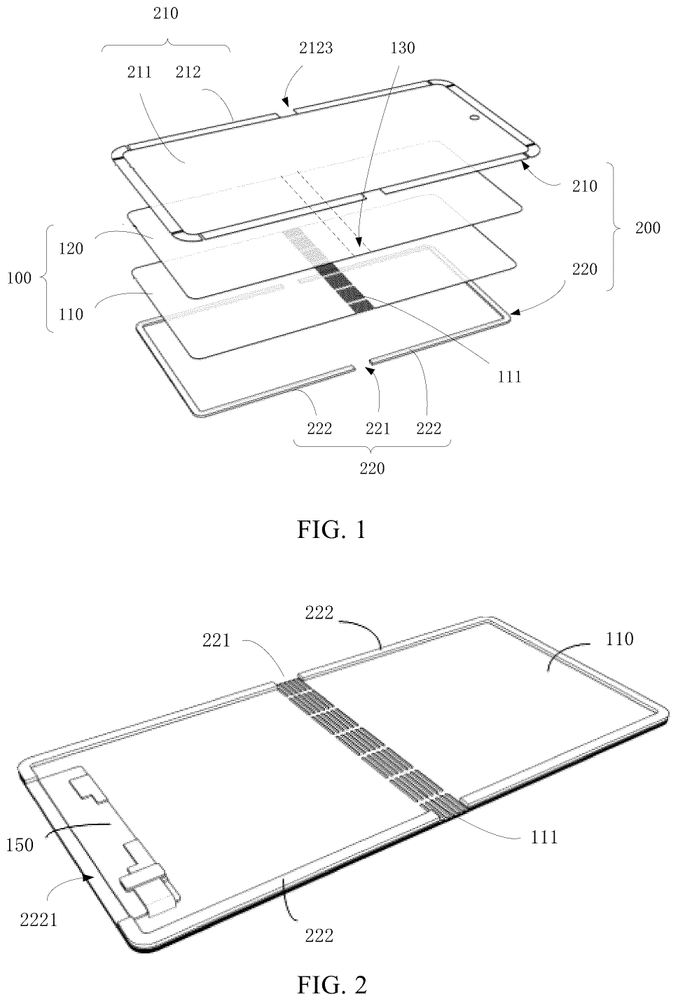

FIG. 1 is a first exploded view illustrating a display device according to one embodiment of the present application.

FIG. 2 is a first assembly view of the display device according to one embodiment of the present application.

FIG. 3 is a first cross-sectional view of the display device according to one embodiment of the present application.

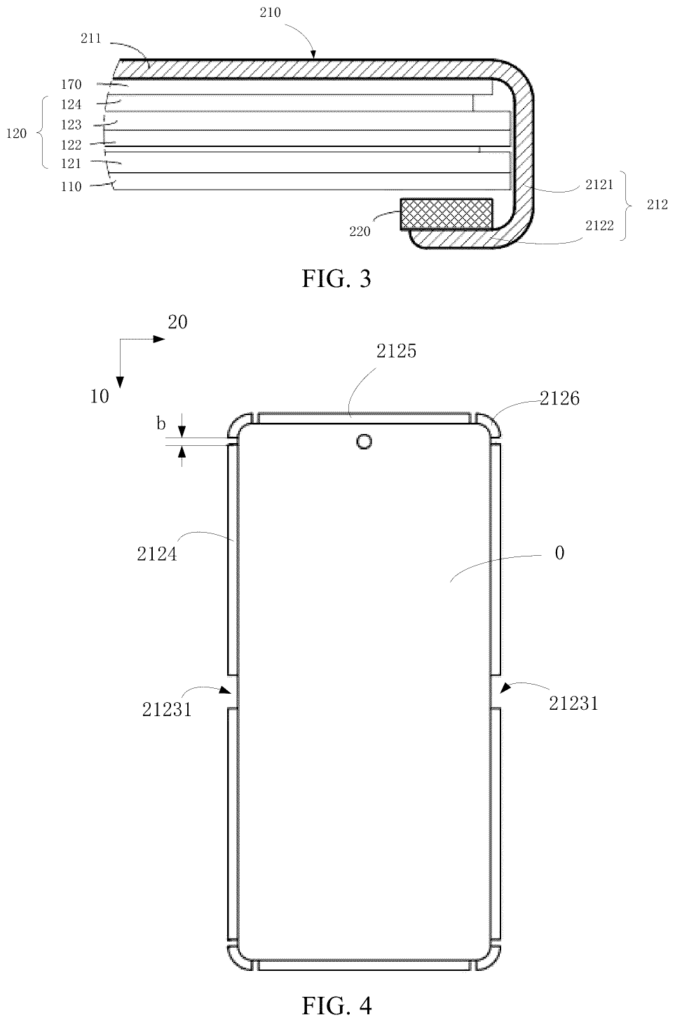

FIG. 4 is a schematic view of a protection layer in the display device according to one embodiment of the present application.

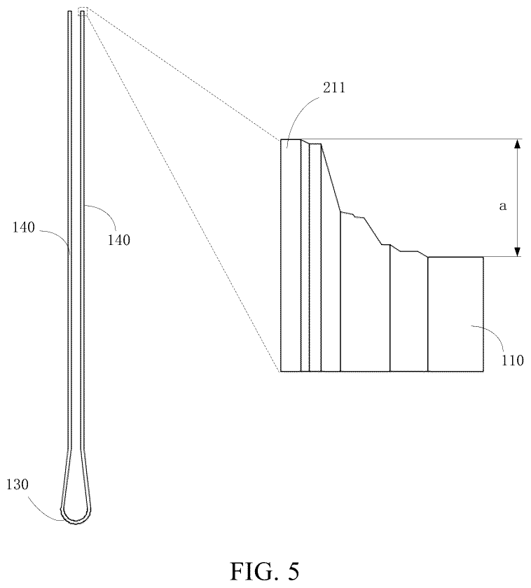

FIG. 5 is a schematic structural view of a display panel in a bent state in the display device according to one embodiment of the present application.

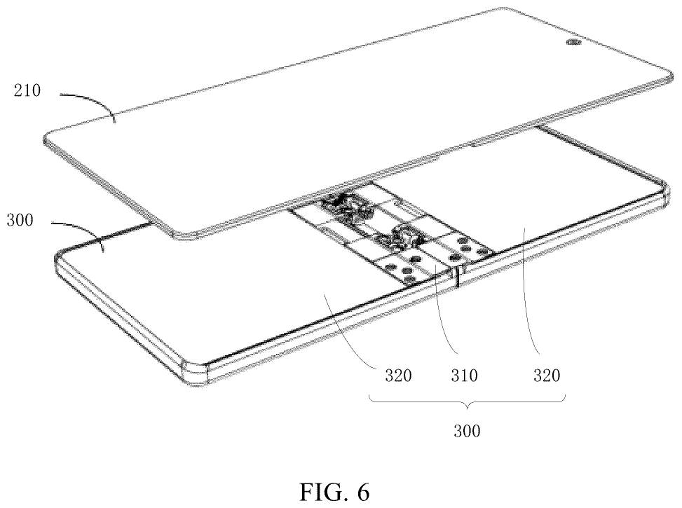

FIG. 6 is a second exploded view of the display device according to one embodiment of the present application.

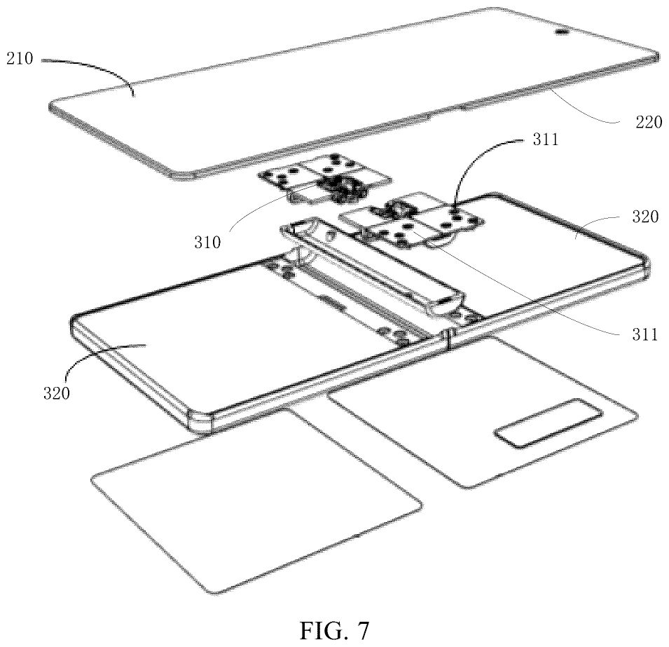

FIG. 7 is a third exploded view of the display device according to one embodiment of the present application.

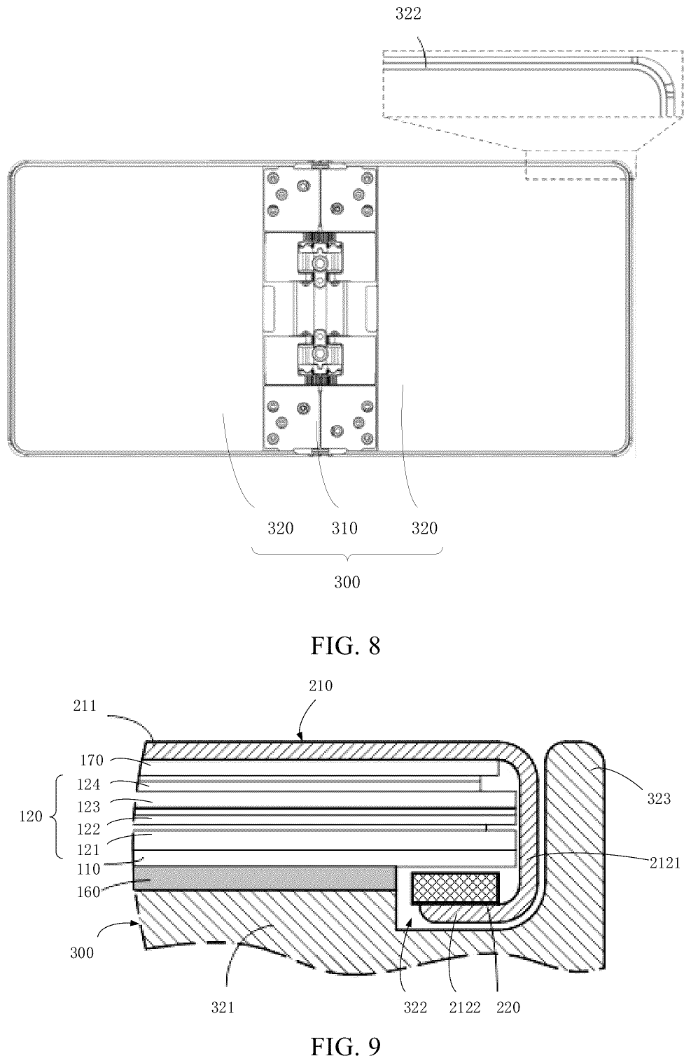

FIG. 8 is a second assembly view of the display device according to one embodiment of the present application.

FIG. 9 is a second cross-sectional view of the display device according to one embodiment of the present application.

### EMBODIMENTS OF INVENTION

### Detailed Description of Preferred Embodiments

The present invention is described with reference to the accompanying drawings and in conjunction with specific embodiments. Directional terms mentioned in the present invention, such as “up”, “down”, “front”, “rear”, “left”, “right”, “inner”, “outer”, and “side”, are only for illustrative purposes based on the directions in the accompanying drawings. Therefore, the directional terms used are for describing and understanding the present invention, not for limiting the present invention. In the drawings, structurally similar elements are denoted by the same reference numerals.

In the following descriptions, it should be understood that the terms “first” and “second” are only used for illustrative purposes, and cannot be interpreted as indicating or implying relative importance or implicitly indicating the number of indicated technical features. Thus, features defined by “first” and “second” may expressly or implicitly include one or more of said features. In the description of the present application, “multiple” means two or more, unless otherwise expressly and specifically defined.

In the description of the present application, it should be noted that, unless otherwise expressly specified and defined, the terms “installed”, “connected”, and “coupled” should be understood in a broad sense. For example, elements can be fixedly connected, detachably connected, or integrally connected. Elements can be mechanically connected or electrically connected, or elements can communicate with each other. Elements can be directly connected or indirectly connected through an intermediate medium. Two elements can have internal communication or interaction. For those of ordinary skill in the art, the specific meanings of the above terms in the present application can be understood on a case-by-case basis.

The technical solutions of the present application are described with reference to specific embodiments.

Referring to FIGS. 1 to 3, the present application provides a display device, including:

a display panel 100 including a support layer 110 and a panel body 120 disposed on the support layer 110;

an encapsulation protection assembly 200 including a protection layer 210 and a frame 220, wherein the frame 220 is disposed on one side of the support layer 110 away from the panel body 120, and the protection layer 210 is disposed on one side of the panel body 120 away from the support layer 110. Edges of the protection layer 210 surround a periphery of the display panel 100, extend to one side of the support layer 110 away from the panel body 120, and are connected to the frame 220.

It can be understood that, at present, signal lines such as gate signal lines, voltage signal lines, driving signal lines are disposed at edges of an organic light-emitting diode (OLED) display device. Usually, edges of the OLED display device are more likely to be damaged by external impact or scratching, especially in a flexible or foldable OLED display device. Therefore, a front frame structure is usually used to protect the OLED display device. However, when the front frame structure is assembled with the OLED display device, it occupies a certain space at the edges of the display device, which reduces a screen ratio and affects an overall visual experience provided by the display device. In the present embodiment, the protection layer 210 is disposed on the side of the panel body 120 away from the support layer 110. The edges of the protection layer 210 surround a periphery of the display panel 100, extend to one side of the support layer 110 away from the panel body 120, and are connected to the frame 220. As a result, the present application realizes encapsulation and provides protection for surfaces and the periphery of the panel body 120 without reducing a screen ratio of the display device.

It should be noted that, in the encapsulation protection assembly 200, the protection layer 210 is disposed on one side of the panel body 120 away from the support layer 110. That is to say, the protection layer 210 is used to protect a light emitting side of the panel body 120. The frame 220 is disposed at one side of the support layer 110 away from the panel body 120 and is used for connecting a connection sub-portion 2122 of the edge protection portion 212 without affecting the screen ratio of the display device. Accordingly, the present application ensures the support rigidity of the edge protection portion 212 encapsulating the periphery of the panel body 120. In the present embodiment, the connection sub-portion 2122 of the edge protection portion 212 can be fixedly connected to the frame 220 by means of thermoplastic molding or adhesive bonding. The protection layer 210 not only has better resistance to scratch and anti-wear properties, but also has high light transmittance. Specifically, the protection layer 210 can be made of one of flexible ultra-thin glass (UTG), colorless Polyimide (CPI), polyethylene terepthalate (PET). The frame 220 can be formed by a press forming process. A material of the frame 220 can include at least one of titanium alloy, magnesium alloy, and aluminum alloy.

It should be noted that, in the present embodiment, the display panel 100 can be a non-flexible display panel that cannot be bent, and the encapsulation protection assembly 200 can be used to encapsulate and protect the surface and side edges of the non-flexible display panel 100. Certainly, the encapsulation protection assembly 200 can also be used to encapsulate and protect a bendable or foldable flexible display panel 100. No matter whether the display panel 100 is a non-flexible display panel 100 or a flexible display panel 100, the encapsulation protection assembly 200 is connected to the display panel 100 through at least the main protection portion 211, so as to achieve encapsulation and provide protection for the surface and the periphery of the display panel 100 by using the encapsulation protection assembly 200.

In one embodiment, as shown in FIGS. 1 to 3, the protection layer 210 includes the main protection portion 211 disposed on one side of the panel body 120 away from the support layer 110, and includes an edge protection portion 212 disposed at a periphery of the main protection portion 211. The edge protection portion 212 includes a lateral side protection sub-portion 2121 arranged around the periphery of the display panel 100, and includes the connection sub-portion 2122 extending from one side of the lateral side protection sub-portion 2121 away from the main protection portion 211 to one side of the support layer 110 away from the panel body 120. The frame 220 is connected to the connection sub-portion 2122 and is located at one side of the support layer 110 away from the panel body 120.

The encapsulation protection assembly 200 is connected to the display panel 100 at least through the main protection portion 211.

It can be understood that by the protection layer 210 is divided into the main protection portion 211, disposed on one side of the panel body 120 away from the support layer 110, and an edge protection portion 212 disposed at a periphery of the main protection portion 211. In addition, the edge protection portion 212 includes the lateral side protection sub-portion 2121 disposed around the periphery of the display panel 100, and includes the connection sub-portion 2122 extending from one side of the lateral side protection sub-portion 2121 away from the main protection portion 211 to one side of the support layer 110 facing away from the panel body 120. The frame 220 is connected to the connection sub-portion 2122 and is located at one side of the support layer 110 away from the panel body 120. Accordingly, the present application can encapsulate and protect the surface and the periphery of the panel body 120 without affecting the screen ratio of the display device. At the same time, the frame 220 and the connection sub-portion 2122 are connected at one side of the support layer 110 away from the panel body 120, so the present application can ensure support rigidity of the edge protection portion 212 encapsulating the periphery of the panel body 120.

In one embodiment, the frame 220 is disposed between the connection sub-portion 2122 and the support layer 110. One side of the frame 220 is connected to the support layer 110, and another side of the frame 220 is connected to the connection sub-section 2122. It can be understood that when the display panel 100 is a non-flexible display panel 100, the support layer 110 can be directly and fixedly connected to the support layer 110, and the support layer 110 and the protection layer 210 can be integrated by means of the frame 220 to provide all-round encapsulation and protection for the panel body 120.

In one embodiment, please refer to FIG. 1 to FIG. 5, the display panel 100 includes a bending display portion 130 and two flat display portions 140 located at two sides of the bending display portion 130.

The frame 220 is spaced apart from the display panel 100, and the frame 220 includes a first opening 221 corresponding to the bending display portion 130.

The edge protection portion 212 is spaced apart from the display panel 100, and the edge protection portion 212 includes a second opening 2123 corresponding to the bending display portion 130.

It can be understood that when the display panel 100 is a flexible display panel, the display panel 100 includes the bending display portion 130, the display panel 100 can be bent at a position of the bending display portion 130, the frame 220 includes the first opening 221 at a position corresponding to the bending display portion 130, and the edge protection portion 212 includes the second opening 2123 at a position corresponding to the bending display portion 130. The frame 220 and the edge protection portion 212 are disconnected at a position corresponding to the bending display portion 130, so as to prevent the frame 220 or the edge protection portion 212 from interfering with the display panel 100 during a bending process of the display panel 100. In addition, the frame 220 is spaced apart from the display panel 100, and the edge protection portion 212 is spaced apart from the display panel 100. Obviously, the encapsulation protection assembly 200 is connected to the display panel 100 through only the main protection portion 211. The frame 220 and the display panel 100 are spaced apart, and the edge protection portion 212 and the display panel 100 are also spaced apart, so the present application prevents the frame 220 or the edge protection portion 212 from being affected by the display panel to cause the main protection portion 211 from peeling off from the display panel 100 during the bending process of the display panel 100.

It should be noted that the frame 220 includes the first opening 221 at a position corresponding to the bending display portion 130, and the edge protection portion 212 includes the second opening 2123 at a position corresponding to the bending display portion 130. On the premise that the frame 220 and the edge protection portion 212 do not affect the bending of the display panel 100, sizes of the first opening 221 and the second opening 2123 do not have a particular limitation.

In this embodiment, as shown in FIGS. 1 to 3, the panel body 120 can include a flexible substrate 121, a display functional layer 122, a polarizer 123, and an ultra-thin flexible glass cover 124 which are stacked on the support layer 110. The support layer 110 is provided with a stress relief structure 111 at a position corresponding to the bending display portion 130. The stress relief structure 111 includes a plurality of through holes or slots defined in the support layer 110, so that the support layer 110 can release stresses during the bending process of the display panel 100. The encapsulation protection assembly 200 can be connected to the ultra-thin flexible glass cover 124 through the main protection portion 211, so that the encapsulation protection assembly 200 is assembled and connected to the display panel 100.

Please refer to FIG. 1 and FIG. 4. In one embodiment, the edge protection portion 212 includes two first protection sections 2124 located on opposite side edges of the display panel 100 respectively, two second protection sections 2125 located at opposite ends of the display panel 100 respectively, and a plurality of corner protection sections 2126 each located at one corner of the display panel 100;

each corner protection section 2126 is disposed between one of the first protection sections 2124 and one of the second protection sections 2125, and the corner protection section 2126 is spaced apart from the first protection section 2124 and the second protection section 2125;

the first protection section 2124 extends along the first direction 10, the bending display portion 130 includes a bending axis extending along the second direction 20, and a predetermined angle is included between the second direction 20 and the first direction 10. The second opening 2123 includes two sub-openings 21231 corresponding to the bending display portion 130, and the two sub-openings 21231 are defined in the two first protection sections 2124, respectively.

It can be understood that different functional film layers such as the support layer 110, the flexible substrate 121, the display functional layer 122, and the polarizer 123 undergo shifting and deformation during the bending process of the display panel 100, resulting in replacement between the different film layers. The edge protection portion 212 is configured to include two first protection sections 2124 respectively located on opposite side edges of the display panel 100 and two second protection sections 2125 respectively located at opposite ends of the display panel 100, and multiple corner protection sections 2126 respectively located at corners of the display panel 100. Furthermore, the corner protection sections 2126 are spaced apart from the first protection sections 2124 and the second protection sections 2125. Such configurations provide sufficient space for the shifting and deformation of the functional film layers during the bending process of the display panel 100. This way, the present application prevents the shifting and deformation of the functional film layers from interfering with the edge protection portion 212 and causing the main protection portion 211 to be peeled off from the display panel 100. Each corner protection section 2126 can be in the shape of a circular arc at a viewing angle perpendicular to the display panel 100, and the corner protection section 2126 can be used for the transition between the first protection section 2124 and the second protection section 2125, so as to encapsulate and protect the corner of the display panel 100.

It should be noted that the first protection section 2124 extends along the first direction 10, the bending display portion 130 includes the bending axis extending along the second direction 20, and a predetermined angle is included between the second direction 20 and the first direction 10. The second opening 2123 includes two sub-openings 21231 corresponding to the bending display portion 130, and the two sub-openings 21231 are defined in the two first protection sections 2124, respectively. In the present embodiment, a length of the first protection section 2124 is greater than a length of the second protection section 2125, and the sub-opening 21231 divides, at a position corresponding to the bending display portion 130, the first protection section 2124 into two parts. The included angle between the first direction 10 and the second direction 20 can be set to 90 degrees.

In one embodiment, please refer to FIG. 4 to FIG. 5, the display panel 100 includes a bent state that bends about the bending axis;

When the display panel 100 is in a bent state, at a side edge of the flat display portion 140 away from the bending display portion 130, a displacement distance from an end surface of the support layer 110 to a plane where an end surface of the main protection portion 211 is located is less than or equal to a predetermined distance a, and a distance between the first protection section 2124 and the corner protection section 2126 is greater than the predetermined distance a.

It can be understood that the display panel 100 can include a flat state and a bent state. When the display panel 100 is in a bent state, the display panel 100 is bent about the bending axis. At this point, different functional film layers such as the support layer 110, the flexible substrate 121, the display functional layer 122, and the polarizer 123 shift and deform during the bending process of the display panel 100, resulting in certain displacement between the different film layers. Obviously, compared with other functional film layers, the displacement distance between the support layer 110 and the main protection portion 211 which are located on opposite sides of the panel body 120 is relatively large. As shown in FIG. 5, the predetermined distance a is the displacement distance between the support layer 110 and the main protection portion 211 when the display panel 100 has the maximum bending angle, and the displacement distance is less than or equal to the predetermined distance a, and the distance between the first protection section 2124 and the corner protection section 2126 is greater than the predetermined distance a, so that the present application can prevent the shifting and deformation of each functional film layer from interfering with the edge protection portion 212 and causing the main protection portion 211 to peel off from the display panel 100. Specifically, the predetermined distance a is equal to 0.32 mm, and a distance b between the first protection section 2124 and the corner protection section 2126 ranges from 0.35 mm to 0.5 mm.

In one embodiment, please refer to FIG. 1 to FIG. 3, the frame 220 includes two sub-frames 222. The two sub-frames 222 are disposed corresponding to the two flat display portions 140 respectively. The two sub-frames 222 are spaced apart at the first openings 221.

In the two flat display portions 140, a flexible circuit board 150 is disposed at one end of one of the flat display portions 140 away from the bending display portion 130.

In the two second protection sections 2125, one of the second protection sections 2125 close to the flexible circuit board 150 is provided with a preset opening (not illustrated) at a position corresponding to the flexible circuit board 150.

In the two sub-frames 222, one of the sub-frames 222 close to the flexible circuit board 150 is provided with a clearance opening 2221 at a position corresponding to the flexible circuit board 150.

It can be understood that, in the two flat display portions 140, one end of one of the flat display portions 140 away from the bending display portion 130 is provided with the flexible circuit board 150. Obviously, by bending a bonding terminal, the flexible circuit board 150 is bonded to one side of the flat display portion 140 away from the main protection portion 211. In the two sub-frames 222, one of the sub-frames 222 close to the flexible circuit board 150 is provided with the clearance opening 2221 at the position corresponding to the flexible circuit board 150. The clearance opening 2221 provides sufficient space for the bending and bonding of the flexible circuit board 150. Furthermore, in the two second protection sections 2125, one of the second protection sections 2125 close to the flexible circuit board 150 is provided with the preset opening at the position corresponding to the flexible circuit board 150. The preset opening facilitates subsequent wiring of power lines or audio lines, etc. at a position of the display device corresponding to the preset opening.

It should be noted that the second protection section 2125 has the preset opening at the position corresponding to the flexible circuit board 150, and a size of the preset opening can be set according to actual needs. The clearance opening 2221 is defined in the sub-frame 222 at the position corresponding to the flexible circuit board 150. Under the premise of avoiding interference between the sub-frame 222 and the flexible circuit board 150, the size of the clearance opening 2221 do not have specific limitations.

In one embodiment, please refer to FIGS. 2 to 5, each sub-frame 222 is U-shaped, and is disposed at an edge of the support layer 110 on one side away from the panel body 120. It can be understood that the sub-frame 222 is U-shaped and disposed along the edge of the display panel 100, which properly ensures the support rigidity of the edge protection portion 212 encapsulating the periphery of the panel body 120.

In one embodiment, please refer to FIG. 6 to FIG. 9, the display device further includes a middle frame 300, and the middle frame 300 includes a bendable hinge 310 disposed corresponding to the bending display portion 130 and two frame bodies 320 connected to the bendable hinge 310. The bendable hinge 310 includes two movable ends 311. The two frame bodies 320 are connected to the two movable ends 311 of the bendable hinge 310, respectively.

Each frame body 320 includes a connecting protrusion 321 and an accommodating groove 322 matched with the sub-frame 222. The connecting protrusion 321 is connected to one side of the support layer 110 away from the panel body 120. The connection sub-portion 2122 and the sub-frame 222 are disposed in the accommodating groove 322. The connection sub-portion 2122 and the middle frame 300 are spaced apart, and the sub-frame 222 and the middle frame 300 are spaced apart.

It can be understood that the frame body 320 includes the connecting protrusion 321 and an accommodating groove 322 matched with the sub-frame 222. The connecting protrusion 321 is connected to one side of the support layer 110 away from the panel body 120. That is to say, the middle frame 300 is connected to the display panel 100 through the connecting protrusion 321, and a shape of the accommodating groove 322 matches a shape of the sub-frame 222 so as to facilitate placing the sub-frame 222 in the accommodating groove 322. Furthermore, the sub-frame 222 and the middle frame 300 are spaced apart, and the connection sub-portions 2122 and the middle frame 300 are spaced apart, so that the sub-frame 222 is in clearance fit with the middle frame 300, and the connection sub-portion 2122 is in clearance fit with the middle frame 300, which reduces the difficulty of assembling the encapsulation assembly and the middle frame 300, and also provides a space between the middle frame 300 and the sub-frame 222 to prevent the frame body 320 and the sub-frame 222 from interfering with each other to cause the main protection portion 211 to be peeled off from the display panel 100 during the bending process of the display device.

In one embodiment, as shown in FIG. 9, the frame body 320 further includes a side frame portion 323 located at one side of the lateral side protection sub-portion 2121 away from the display panel 100. The accommodating groove 322 is located between the connecting protrusion 321 and the side frame portion 323, and the lateral side protection sub-portion 2121 and the side frame portion 323 are spaced apart.

It can be understood that the frame body 320 further includes the side frame portion 323 located on one side of the lateral side protection sub-portion 2121 away from the display panel 100. Obviously, the side frame portion 323 can better realize the protection for the periphery of the display panel 100. Furthermore, the accommodating groove 322 is located between the connecting protrusion 321 and the side frame portion 323, and the lateral side protection sub-portion 2121 and the side frame portion 323 are spaced apart. Under the condition that the side frame portion 323 protects the periphery of the display panel 100, the lateral side protection sub-portion 2121 and the side frame portion 323 are arranged spaced apart, which also prevents the frame body 320 and the sub-frame 222 from interfering with each other to cause the main protection portion 211 to be peeled off from the display panel 100 during the bending process of the display device.

Please refer to FIG. 9, in one embodiment, a first adhesive layer 160 is disposed on one side of the connecting protrusion 321 close to the support layer 110, and the connecting protrusion 321 is connected to the support layer 110 through the first adhesive layer 160.

It can be understood that the connecting protrusion 321 can be connected to the support layer 110 through the first adhesive layer 160, thereby improving the convenience and reliability of assembling the middle frame 300 and the display panel 100 in the display device. Specifically, the first adhesive layer 160 can be a mesh adhesive tape, sealant, or a removable adhesive tape.

Please refer to FIG. 3 and FIG. 9, in one embodiment, a second adhesive layer 170 is disposed on one side of the main protection portion 211 close to the panel body 120, and the main protection portion 211 is bonded to the panel body 120 through the second adhesive layer 170.

It can be understood that the main protection portion 211 can be bonded to the panel body 120 through the second adhesive layer 170, thereby improving the convenience and reliability of assembling the protection layer 210 and the display panel 100 in the display device. Specifically, a material of the second adhesive layer 170 can be an optical clear adhesive.

In present application, the protection layer 210 is disposed on one side of the panel body 120 away from the support layer 110. The edges of the protection layer 210 surround the periphery of the display panel 100, extend to one side of the support layer 110 away from the panel body 120, and are connected to the frame 220. Accordingly, the present application realizes encapsulation and protection for the surfaces and the periphery of the panel body 120 without reducing the screen ratio of the display device.

In summary, although the present invention has been disclosed above with reference to preferable embodiments, the above preferable embodiments are not intended to limit the present invention. Those of ordinary skill in the art can make various modifications and changes. Therefore, the protection scope of the present invention is defined by the accompanying claims.

What is claimed is:

1. A display device, comprising. a display panel comprising a support layer and a panel body disposed on the support layer; and
an encapsulation protection assembly comprising a protection layer and a frame, wherein the frame is disposed on one side of the support layer away from the panel body, and the protection layer is disposed on one side of the panel body away from the support layer, wherein edges of the protection layer surround a periphery of the display panel, extend to one side of the support layer away from the panel body, and are connected to the frame.

2. The display device according to claim 1, wherein the protection layer comprises a main protection portion disposed on one side of the panel body away from the support layer and comprises an edge protection portion disposed at a periphery of the main protection portion, the edge protection portion comprises a lateral side protection sub-portion disposed around the periphery of the display panel and an connection sub-portion extending from one side of the lateral side protection sub-portion away from the main protection portion to one side of the support layer facing away from the panel body, and the frame is connected to the connection sub-portion and disposed on one side of the support layer away from the panel body; and
wherein the encapsulation protection assembly is connected to the display panel at least through the main protection portion.

3. The display device according to claim 2, wherein the display panel comprises a bending display portion and two flat display potions disposed at two sides of the bending display portion;
the frame is spaced apart from the display panel, and the frame comprises a first opening at a position corresponding to the bending display portion; and
the edge protection portion is spaced apart from the display panel, and the edge protection portion comprises a second opening at a position corresponding to the bending display portion.

4. The display device according to claim 3, wherein the edge protection portion comprises two first protection sections disposed on opposite side edges of the display panel, two second protection sections disposed on opposite ends of the display panel, and a plurality of corner protection sections each disposed at a corner of the display panel;
each of the corner protection sections is disposed between one of the first protection sections and one of the second protection sections, each of the corner protection section is spaced apart from one of the first protection sections, and each of the corner protection sections is spaced apart from one of the second protection sections; and
the first protection section extends along a first direction, the bending display portion comprises a bending axis extending along a second direction, a predetermined angle is included between the second direction and the first direction, the second opening comprises two sub-openings corresponding to the bending display portion, and the two sub-openings are arranged in the two first protection sections respectively.

5. The display device according to claim 4, wherein the display panel comprises a bent state which bending about the bending axis;
when the display panel is in the bent state, at a side edge of one of the flat display portions away from the bending display portion, a displacement distance from an end surface of the support layer to a plane where an end surface of the main protection portion is located is less than or equal to a predetermined distance, and a distance between one of the first protection sections and an adjacent one of the corner protection sections is greater than the predetermined distance.

6. The display device according to claim 4, wherein the frame comprises two sub-frames, each of the sub-frames is disposed corresponding to one of the flat display portions, and the two sub-frames are spaced apart at the first openings;
in the two flat display portions, a flexible circuit board is disposed at one end of one of the flat display portions away from the bending display portion;
in the two second protection sections, one of the second protection sections close to the flexible circuit board is provided with a preset opening at a position corresponding to the flexible circuit board; and
in the two sub-frames, one of the sub-frames close to the flexible circuit board is provided with a clearance opening at a position corresponding to the flexible circuit board.

7. The display device according to claim 6, wherein each of the sub-frames is U-shaped and is disposed at an edge of the support layer on one side away from the panel body.

8. The display device according to claim 6, wherein the display device further comprises a middle frame, the middle frame comprises a bendable hinge disposed corresponding to the bending display portion and two frame bodies respectively connected with the bendable hinge, the bendable hinge includes two movable ends, and the two frame bodies are connected to the two movable ends of the bending hinge respectively; and
each of the frame bodies includes a connecting protrusion and an accommodating groove matched with one of the sub-frames, each of the connecting protrusions is connected to one side of the support layer away from the panel body, the connection sub-portion and the sub-frames are disposed in the accommodating grooves, the connection sub-portion is spaced apart from the middle frame, and the sub-frames are spaced apart from the middle frame.

9. The display device according to claim 8, wherein each of the frame bodies further comprises a side frame portion disposed at one side of the lateral side protection sub-portion away from the display panel; in each of the frame bodies, the accommodating groove is located between the connecting protrusion and the side frame portion; and the lateral side protection sub-section is spaced apart from the side frame portions.

10. The display device according to claim 8, wherein a first adhesive layer is disposed on one side of the connecting protrusion close to the support layer, and the connecting protrusion is connected to the support layer through the first adhesive layer.

11. The display device according to claim 2, wherein a second adhesive layer is disposed on one side of the main protection portion close to the panel body, and the main protection portion is connected to the panel body through the second adhesive layer.

12. The display device according to claim 2, wherein the frame is disposed between the connection sub-section and the support layer, one side of the frame is connected to the support layer, and another side of the frame is connected to the connection sub-portion.

13. A display device, comprising:
a display panel comprising a support layer and a panel body disposed on the support layer; and
an encapsulation protection assembly comprising a protection layer and a frame, wherein the frame is disposed on one side of the support layer away from the panel body, and the protection layer is disposed on one side of the panel body away from the support layer, wherein edges of the protection layer surround a periphery of the display panel, extend to one side of the support layer away from the panel body, and are connected to the frame;
wherein the protection layer comprises a main protection portion disposed on one side of the panel body away from the support layer and comprises an edge protection portion disposed at a periphery of the main protection portion, the edge protection portion comprises a lateral side protection sub-portion disposed around the periphery of the display panel and an connection sub-portion extending from one side of the lateral side protection sub-portion away from the main protection portion to one side of the support layer facing away from the panel body, and the frame is connected to the connection sub-portion and disposed on one side of the support layer away from the panel body;
the encapsulation protection assembly is connected to the display panel at least through the main protection portion;
the display panel comprises a bending display portion and two flat display potions disposed at two sides of the bending display portion;
the frame is spaced apart from the display panel, and the frame comprises a first opening at a position corresponding to the bending display portion;
the edge protection portion is spaced apart from the display panel, and the edge protection portion comprises a second opening at a position corresponding to the bending display portion; and
a second adhesive layer is disposed on one side of the main protection portion close to the panel body, and the main protection portion is connected to the panel body through the second adhesive layer.

14. The display device according to claim 13, wherein the edge protection portion comprises two first protection sections disposed on opposite side edges of the display panel, two second protection sections disposed on opposite ends of the display panel, and a plurality of corner protection sections each disposed at a corner of the display panel;
each of the corner protection sections is disposed between one of the first protection sections and one of the second protection sections, each of the corner protection section is spaced apart from one of the first protection sections, and each of the corner protection sections is spaced apart from one of the second protection sections; and
the first protection section extends along a first direction, the bending display portion comprises a bending axis extending along a second direction, a predetermined angle is included between the second direction and the first direction, the second opening comprises two sub-openings corresponding to the bending display portion, and the two sub-openings are arranged in the two first protection sections respectively.

15. The display device according to claim 14, wherein the display panel comprises a bent state which bending about the bending axis;
when the display panel is in the bent state, at a side edge of one of the flat display portions away from the bending display portion, a displacement distance from an end surface of the support layer to a plane where an end surface of the main protection portion is located is less than or equal to a predetermined distance, and a distance between one of the first protection sections and an adjacent one of the corner protection sections is greater than the predetermined distance.

16. The display device according to claim 14, wherein the frame comprises two sub-frames, each of the sub-frames is disposed corresponding to one of the flat display portions, and the two sub-frames are spaced apart at the first openings;
in the two flat display portions, a flexible circuit board is disposed at one end of one of the flat display portions away from the bending display portion;
in the two second protection sections, one of the second protection sections close to the flexible circuit board is provided with a preset opening at a position corresponding to the flexible circuit board; and
in the two sub-frames, one of the sub-frames close to the flexible circuit board is provided with a clearance opening at a position corresponding to the flexible circuit board.

17. The display device according to claim 16, wherein each of the sub-frames is U-shaped and is disposed at an edge of the support layer on one side away from the panel body.

18. The display device according to claim 16, wherein the display device further comprises a middle frame, the middle frame comprises a bendable hinge disposed corresponding to the bending display portion and two frame bodies respectively connected with the bendable hinge, the bendable hinge includes two movable ends, and the two frame bodies are connected to the two movable ends of the bending hinge respectively; and
each of the frame bodies includes a connecting protrusion and an accommodating groove matched with one of the sub-frames, each of the connecting protrusions is connected to one side of the support layer away from the panel body, the connection sub-portion and the sub-frames are disposed in the accommodating grooves, the connection sub-portion is spaced apart from the middle frame, and the sub-frames are spaced apart from the middle frame.

19. The display device according to claim 18, wherein each of the frame bodies further comprises a side frame portion disposed at one side of the lateral side protection sub-portion away from the display panel; in each of the frame bodies, the accommodating groove is located between the connecting protrusion and the side frame portion; and the lateral side protection sub-section is spaced apart from the side frame portions.

20. The display device according to claim 18, wherein a first adhesive layer is disposed on one side of the connecting protrusion close to the support layer, and the connecting protrusion is connected to the support layer through the first adhesive layer.
